(19) United States
(12) Patent Application Publication
(10) Pub. No.: US 2026/0040670 A1
(43) Pub. Date: Feb. 5, 2026

(54) METHOD AND APPARATUS FOR COMPLEMENTARY METAL OXIDE SEMICONDUCTOR (CMOS) INTEGRATED THERMOPILE DESIGN

(71) Applicant: QUALCOMM Incorporated, San Diego, CA (US)

(72) Inventors: Abhijeet PAUL, San Diego, CA (US); Mishel MATLOUBIAN, San Diego, CA (US); Periannan CHIDAMBARAM, San Diego, CA (US)

(21) Appl. No.: 18/792,065

(22) Filed: Aug. 1, 2024

(51) Int. Cl. H01L 27/092; H01L 21/762; H01L 23/00; H01L 25/065

(52) U.S. Cl. CPC H10D 84/85; H01L 21/76243; H01L 24/16; H01L 25/0657; H01L 2224/16225; H01L 2225/06555; H01L 2924/14

(57) ABSTRACT

An integrated circuit (IC) is described. The IC includes a substrate supporting a buried oxide (BOX) layer. The IC also includes a first-type semiconductor layer on the BOX layer. The IC further includes an oxide layer on the first-type semiconductor layer. The IC also includes a second-type semiconductor layer on the oxide layer, in which a perforated portion of the first-type semiconductor layer is exposed through an opening in the second-type semiconductor layer and the oxide layer. The IC further includes a contact between the first-type semiconductor layer and the second-type semiconductor layer. The IC also includes the BOX layer defining a cavity and partially in the substrate.

### BACKGROUND

### Field

Aspects of the present disclosure relate to integrated circuits (ICs) and, more particularly, to a method and apparatus for a complementary metal oxide semiconductor (CMOS) thermopile design.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to thermal issues when multiple dies are stacked in the small form factor.

### SUMMARY

An integrated circuit (IC) is described. The IC includes a substrate supporting a buried oxide (BOX) layer. The IC also includes a first-type semiconductor layer on the BOX layer. The IC further includes an oxide layer on the first-type semiconductor layer. The IC also includes a second-type semiconductor layer on the oxide layer, in which a perforated portion of the first-type semiconductor layer is exposed through an opening in the second-type semiconductor layer and the oxide layer. The IC further includes a contact between the first-type semiconductor layer and the second-type semiconductor layer. The IC also includes the BOX layer defining a cavity and partially in the substrate.

A method for forming a complementary metal oxide semiconductor (CMOS) thermopile structure is described. The method includes forming a cavity in a buried oxide (BOX) layer and partially in a substrate supporting the BOX layer. The method also includes forming a first-type semiconductor layer on the BOX layer. The method further includes forming an oxide layer on the first-type semiconductor layer. The method also includes forming a second-type semiconductor layer on the oxide layer, in which a perforated portion of the first-type semiconductor layer is exposed through an opening in the second-type semiconductor layer and the oxide layer. The method further includes forming a contact between the first-type semiconductor layer and the second-type semiconductor layer.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-a-chip (SOC), including a complementary metal oxide semiconductor (CMOS) thermopile design, in accordance with certain aspects of the present disclosure.

FIG. 2 shows a cross-sectional view of a stacked integrated circuit (IC) package of the host system-on-a-chip (SOC) of FIG. 1.

FIG. 3 shows a cross-sectional view illustrating the stacked integrated circuit (IC) package of FIG. 2, incorporated into a wireless device, according to one aspect of the present disclosure.

FIGS. 4A-4E are schematic diagrams illustrating a complementary metal oxide semiconductor (CMOS) thermopile design having a perforated semiconductor layer, according to various aspects of the present disclosure.

FIGS. 5A-5C are schematic diagrams illustrating a complementary metal oxide semiconductor (CMOS) thermopile design having a perforated semiconductor layer, according to various aspects of the present disclosure.

FIGS. 6A-6C are schematic diagrams illustrating a complementary metal oxide semiconductor (CMOS) thermopile design having a perforated semiconductor layer, according to various aspects of the present disclosure.

FIGS. 7A and 7B are schematic diagrams illustrating a complementary metal oxide semiconductor (CMOS) thermopile design having a perforated semiconductor layer, according to various aspects of the present disclosure.

FIG. 8 is a process flow diagram illustrating a method for fabricating a complementary metal oxide semiconductor (CMOS) thermopile structure, according to various aspects of the present disclosure.

FIG. 9 is a block diagram showing an exemplary wireless communications system, in which an aspect of the present disclosure may be advantageously employed.

FIG. 10 is a block diagram illustrating a design workstation used for circuit, layout, and logic design of a semiconductor component such as the complementary metal oxide semiconductor (CMOS) thermopile structure disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to thermal issues when multiple dies are stacked in the small form factor.

It is desirable to sense temperature of a system-on-a chip (SOC) in smartphones. Modern microprocessor control algorithms in smartphones make use of the temperature of the SOC to mitigate performance. As a result, temperature accuracy is important in reliability assessment of products. In practice, temperature sensors are conventionally used to sense a temperature of an SOC in a smartphone. Sensing external radiation (IR)/temperature may involve a complementary oxide semiconductor (CMOS) integrated process. One current state-of-the-art CMOS integrated temperature sensing device relies on dual polysilicon layers, which involves a specialized process flow during a fabrication process.

Various aspects of the present disclosure provide a CMOS thermopile design. The process flow for fabrication of the CMOS thermopile design may include existing CMOS and interconnect layers. These interconnections include back-end-of-line (BEOL) layers, which may refer to the conductive interconnect layers for electrically coupling to front-end-of-line (FEOL) active devices of an integrated circuit (IC). The various BEOL interconnect layers are formed at corresponding BEOL interconnect levels, in which lower BEOL interconnect levels use thinner metal layers relative to upper BEOL interconnect levels. The BEOL interconnect layers may electrically couple to middle-of-line (MOL) interconnect layers, which interconnect to the FEOL active devices of an IC.

It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Various aspects of the present disclosure are directed to a method and apparatus for implementation of an efficient thermopile using the existing CMOS layers with structural improvements. In various aspects of the present disclosure, these structural improvements include perforation in a semiconductor layer (e.g., a silicon diffusion layer). Additionally, the structural variations include staggered (e.g., vertically offset) positioning of the diffusion regions and the polysilicon layers. This CMOS thermopile structure supplies a desired delta in a Seebeck coefficient along with lower thermal conductivity through the material. In particular, the CMOS thermopile structure maintains a temperature delta between the hot and cold regions of a device.

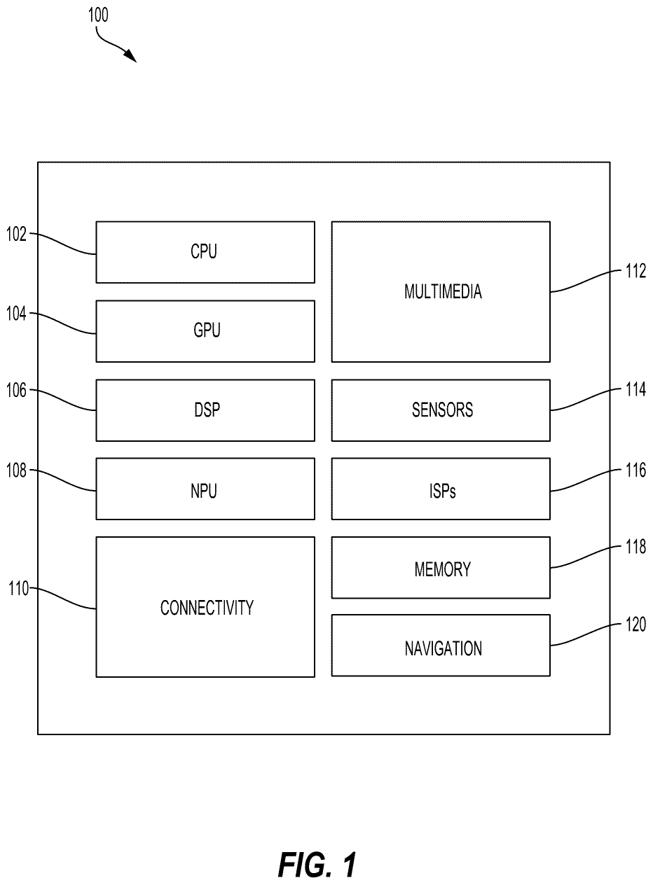

FIG. 1 illustrates an example implementation of a host system-on-a-chip (SOC) 100, which includes a complementary metal oxide semiconductor (CMOS) thermopile design, in accordance with certain aspects of the present disclosure. The host SOC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SOC 100 includes various processing units that support multi-threaded operation. For the configuration shown in FIG. 1, the host SOC 100 includes a multi-core central processing unit (CPU) 102, a graphics processor unit (GPU) 104, a digital signal processor (DSP) 106, and a neural processor unit (NPU) 108. The host SOC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

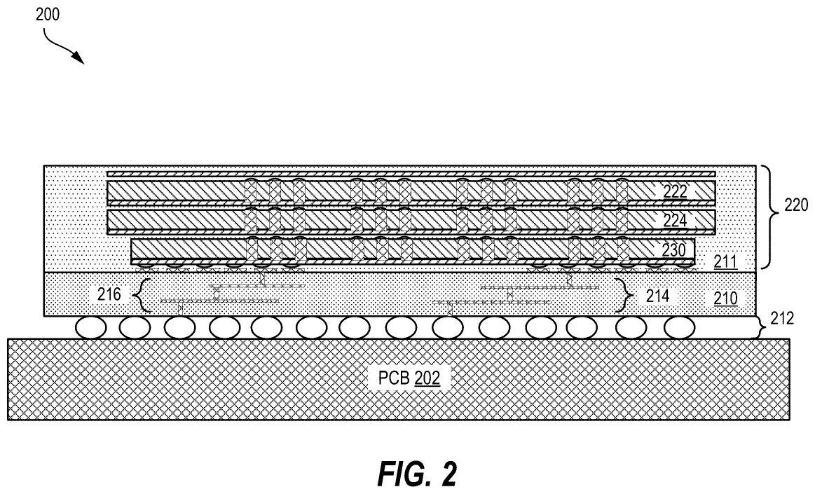

FIG. 2 shows a cross-sectional view of a stacked integrated circuit (IC) package 200 of the host system-on-a-chip (SOC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SOC 100 of FIG. 1.

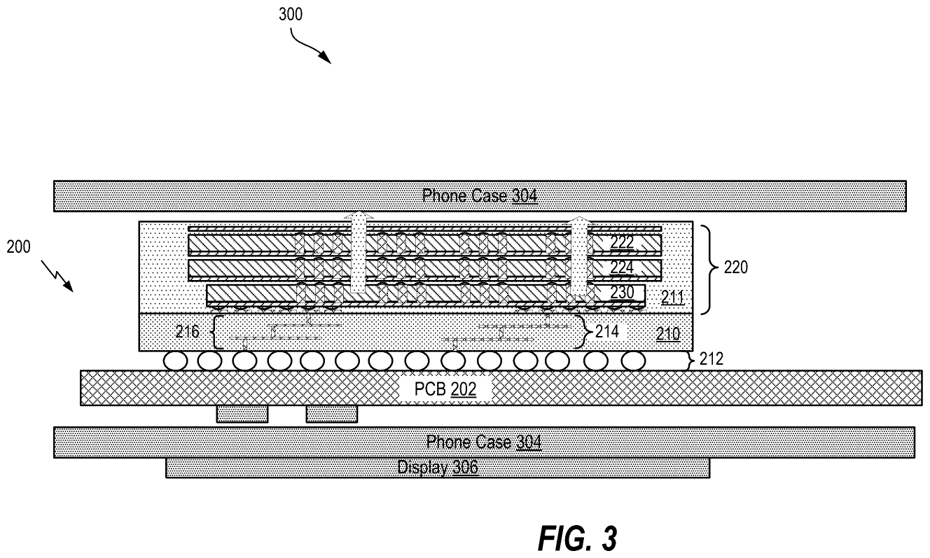

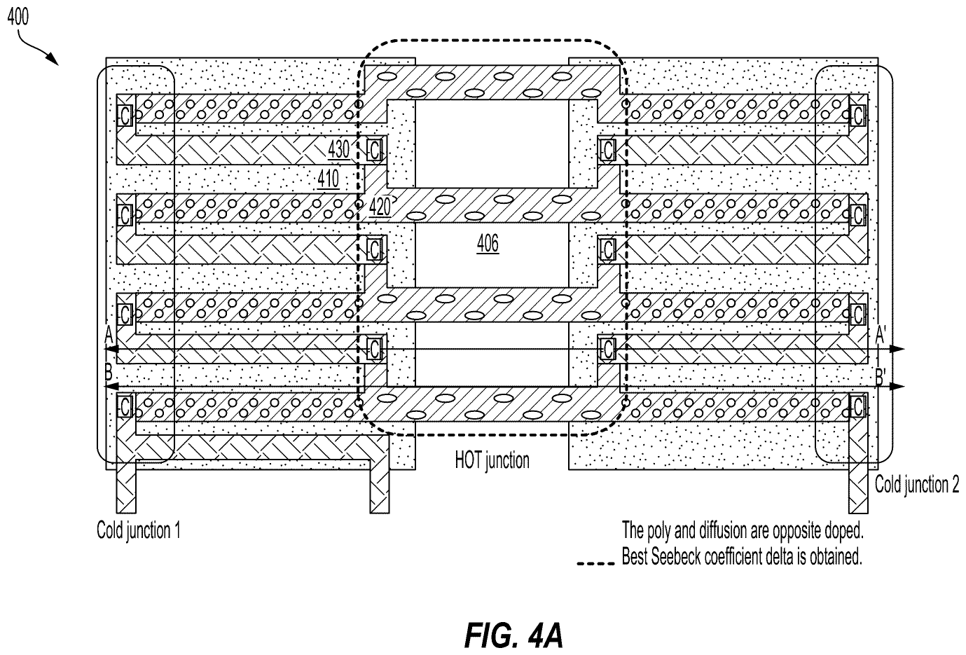

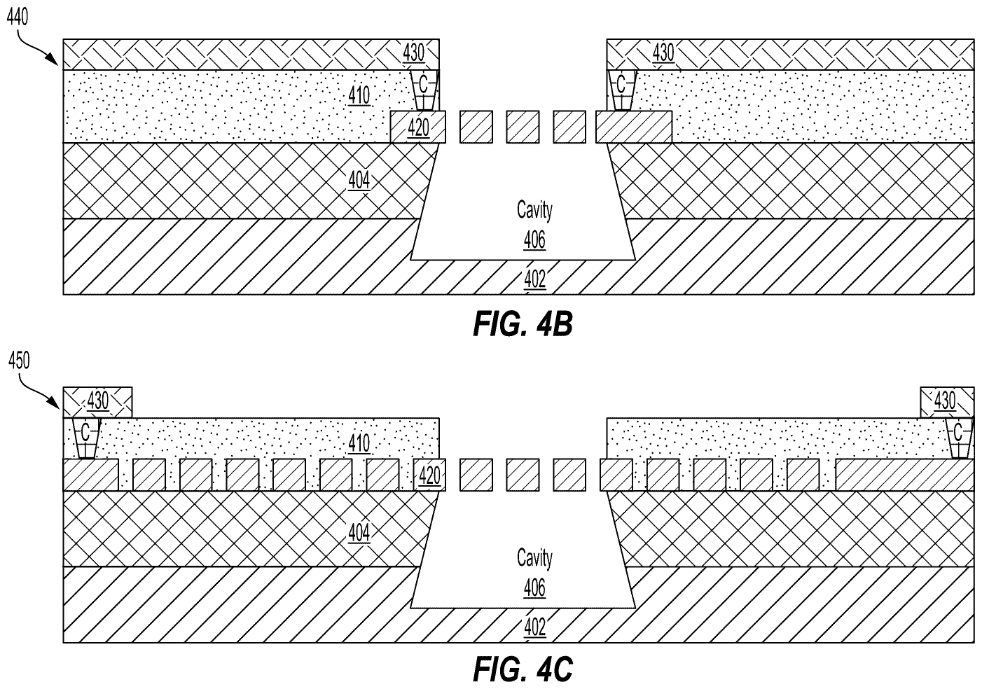

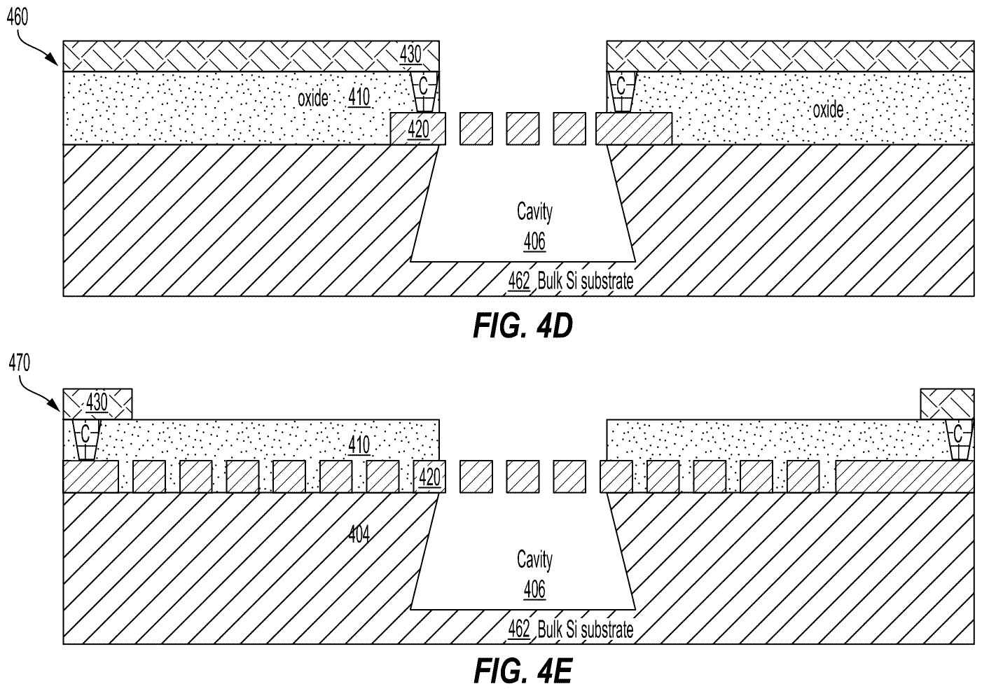

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications. Representatively, the stacked IC package 200 is within a phone case 304, including a display 306. In this configuration, a complementary metal oxide semiconductor (CMOS) thermopile design is integrated in the stacked IC package 200 to support improved thermal sensing, for example, as shown in FIGS. 4A to 7B.

FIGS. 4A-4E are schematic diagrams illustrating a complementary metal oxide semiconductor (CMOS) thermopile design 400 having a perforated semiconductor layer, according to various aspects of the present disclosure. FIG. 4A is a schematic diagram illustrating an overhead layout view of the thermopile design 400, including a cavity 406 proximate a hot junction (HJ) between portions of an oxide layer 410 having a first cold junction (CJ1) and a second cold junction (CJ2). In this example, the thermopile design 400 is composed of first-type semiconductor layers 420 and second-type semiconductor layers 430.

In various aspects of the present disclosure, the first-type semiconductor layers 420 and the second-type semiconductor layers 430 are staggered and vertically offset with structural improvements. This arrangement of the first-type semiconductor layers 420 and the second-type semiconductor layers 430 ensures a desired delta (e.g., 0.8-1.5 mV/K) in the Seebeck coefficient (coeff) along with lower thermal conductivity through the material by maintaining a temperature delta between the HJ region and the CJ1 and CJ2 regions.

In some implementations, the first-type (e.g., N-type/P-type) semiconductor layers 420 are composed of a diffused silicon material, including, but not limited to, silicon (Si) doped with a Ptype material (e.g., boron) or doped with an Ntype material (e.g., arsenic, phosphorus), or other like doped, semiconductor material. In some implementations, the second-type (e.g., P-type/N-type) semiconductor layers 430 are composed of a polysilicon material, including, but not limited to, polysilicon doped with a Ptype material (e.g., boron) or doped with an Ntype (e.g., Arsenic, Phosphorus), or other like doped, polysilicon material.

In various aspects of the present disclosure, one structural improvement is provided in the form of perforations in the first-type semiconductor layers 420, which trades-off between electron mobility and bulk thermal conductivity. In some implementations, a non-uniform distribution is utilized for arranging the perforations, which maximizes heat blockage (e.g., due to atomic vibration or phonons), while having minimal impact on the electron flow. Conversely, an even placement of the perforations in the first-type semiconductor layers 420 prevents the atomic vibration or phonons phenomena noted-above and, hence, would lead to an efficiency drop of the thermopile design 400.

Regarding the trade-off between electron mobility and bulk thermal conductivity, it is noted that in semiconductor materials (unlike metals), electrons mostly conduct electricity (and minimal heat transport). Most of the heat transport occurs in response to atomic lattice vibrations (e.g., phonons). Consequently, a non-uniform distribution of the perforations as well as a poly-crystallinity of the semiconductor material enhances an electron flow (as electrons are smaller), while blocking/damping the atomic vibration leading to heat blockage. This blocking/damping of the atomic vibration allows the hot junction to remain hot and cold to remain cold, thus allowing for a better seebeck effect (meaning more voltage generation).

FIG. 4B is a schematic diagram illustrating a cross-sectional view of the thermopile design 400 of FIG. 4A along a cutline AA′, according to various aspects of the present disclosure. As shown in FIG. 4B, a thermopile structure 440 includes a substrate 402 supporting a buried oxide (BOX) layer 404. In this semiconductor-on-insulator (SOI) implementation, the thermopile structure 440 includes first-type semiconductor layers 420 on portions of the BOX layer 404. Additionally, the thermopile structure 440 includes the oxide layer 410 on the first-type semiconductor layers 420 and second-type semiconductor layers 430 on the oxide layer 410.

In various aspects of the present disclosure, a perforated portion of the first-type semiconductor layers 420 is exposed through an opening in the second-type semiconductor layers 430 and the oxide layer 410. The thermopile structure 440 further includes a contact (C) between the first-type semiconductor layers 420 and the second-type semiconductor layers 430. According to various aspects of the present disclosure, the thermopile structure 440 includes a cavity 406 through the BOX layer 404 and partially in the substrate 402, proximate the HJ region, as shown in FIG. 4A.

FIG. 4C is a schematic diagram illustrating a cross-sectional view of the thermopile design 400 of FIG. 4A along a cutline BB′, according to various aspects of the present disclosure. As shown in FIG. 4C, a thermopile structure 450 is like the thermopile structure 440 of FIG. 4B and is described using similar reference numbers. As shown in FIG. 4C, the first-type semiconductor layers 420 are perforated and extend along the BOX layer 404 and across the cavity 406. Additionally, the thermopile structure 450 includes the second-type semiconductor layers 430 on portions of the oxide layer 410 at the edges of the thermopile structure 450, proximate the CJ1 and CJ2 regions, as shown in FIG. 4A. The thermopile structure 450 further includes contacts (C) between the first-type semiconductor layers 420 and the second-type semiconductor layers 430 at the edges of the thermopile structure 450, rather than the edges of the cavity 406, as shown in FIG. 4B.

FIG. 4D is a schematic diagram illustrating a cross-sectional view of the thermopile design 400 of FIG. 4A along a cutline AA′, according to various aspects of the present disclosure. As shown in FIG. 4D, a thermopile structure 460 is like the thermopile structure 440 of FIG. 4B and is described using similar reference numbers. As shown in FIG. 4D, the SOI implementation of FIG. 4B is replaced with a bulk semiconductor substrate 462, including the cavity 406. In various aspects of the present disclosure, the bulk semiconductor substrate implementation shown in FIG. 4D may be implemented at a reduced cost relative to the SOI implementation shown in FIG. 4B because SOI wafer are more costly (e.g., 2×-6×) than bulk semiconductor substrates.

FIG. 4E is a schematic diagram illustrating a cross-sectional view of the thermopile design 400 of FIG. 4A along a cutline BB′, according to various aspects of the present disclosure. As shown in FIG. 4E, a thermopile structure 470 is like the thermopile structure 450 of FIG. 4C and is described using similar reference numbers. As shown in FIG. 4E, the SOI implementation of FIGS. 4B and 4C is replaced with the bulk semiconductor substrate 462, including the cavity 406, which may reduce cost relative to the SOI implementation shown in FIG. 4C. Additionally, the thermopile structure 470 includes the second-type semiconductor layers 430 on portions of the oxide layer 410 at the edges of the thermopile structure 470, proximate the CJ1 and CJ2 regions, as shown in FIG. 4A. The thermopile structure 470 further includes contacts (C) between the first-type semiconductor layers 420 and the second-type semiconductor layers 430 at the edges of the thermopile structure 470, rather than the edges of the cavity 406, as shown in FIG. 4D.

As shown in FIGS. 4A-4E, the thermopile design 400 is formed using an existing CMOS flow as well as existing diffusion layers (e.g., first-type semiconductor layers 420) and polysilicon layers (e.g., second-type semiconductor layers 430). According to various aspects of the present disclosure, a non-uniform distributions of the perforations in the first-type semiconductor layers 420 enhances thermal flow reduction from the HJ region by blocking/damping of the atomic vibration, resulting in an improved Seebeck coefficient due to enhanced. This configuration of the first-type semiconductor layers 420 allows for developing radiation thermal infrared (IR) sensors. Additionally, the cavity 406 in the thermopile designs based on the SOI implementations shown in FIGS. 4B and 4C as well as the bulk semiconductor substrate implementations shown in FIGS. 4D and 4E provide enhanced sensitivity and reduced heat loss from the HJ region, as shown in FIG. 4A.

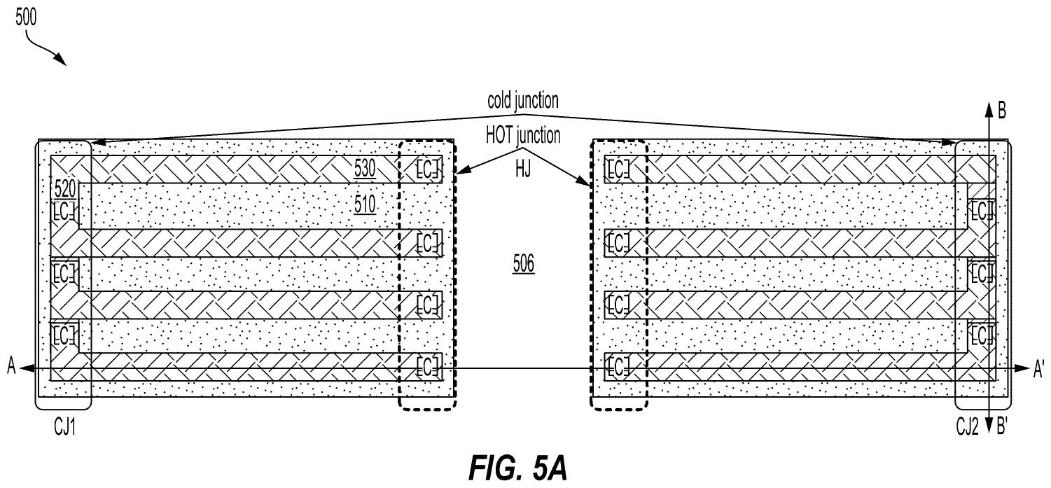

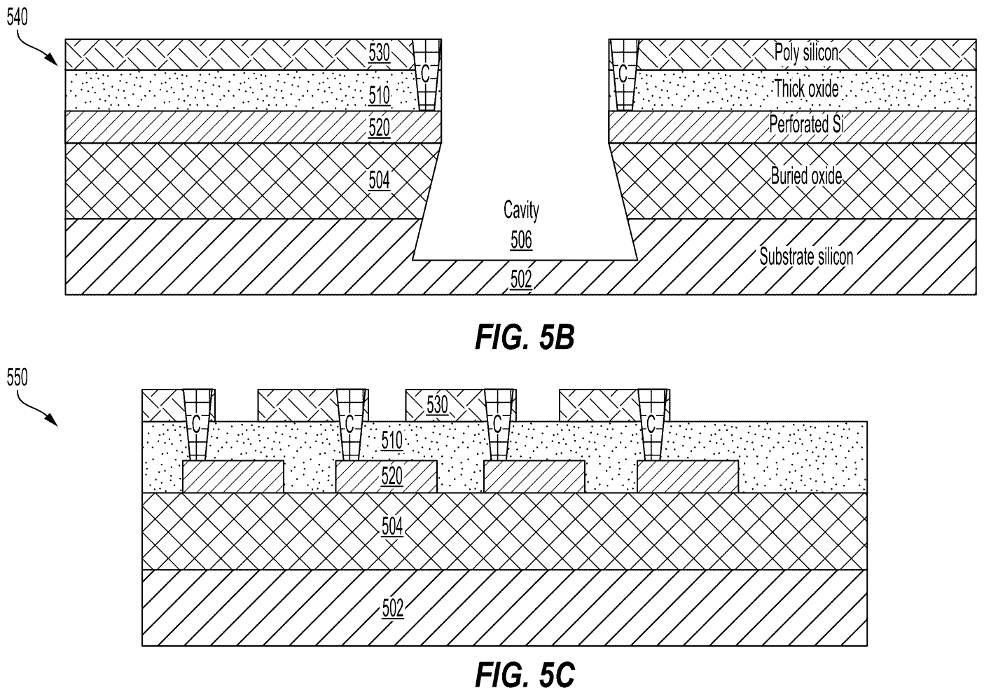

FIGS. 5A-5C are schematic diagrams illustrating a complementary metal oxide semiconductor (CMOS) thermopile design 500 having a perforated semiconductor layer, according to various aspects of the present disclosure. FIG. 5A is a schematic diagram illustrating an overhead layout view (or plane view) of the thermopile design 500, including a cavity 506 proximate a hot junction (HJ) between portions of an oxide layer 510 having a first cold junction (CJ1) and a second cold junction (CJ2). In this example, the thermopile design 500 is composed of first-type semiconductor layers 520 (e.g., diffusion regions) and second-type semiconductor layers 530 (e.g., polysilicon layers).

In various aspects of the present disclosure, the first-type semiconductor layers 520 and the second-type semiconductor layers 530 are staggered and vertically offset with structural improvements. This arrangement of the first-type semiconductor layers 520 and the second-type semiconductor layers 530 ensures a desired delta (e.g., 0.8-1.5 mV/K) in the Seebeck coefficient by maintaining a temperature delta between the HJ region and the CJ1 and CJ2 regions. In some implementations, the first-type (e.g., N-type/P-type doped) semiconductor layers 520 may be composed of a doped silicon material, including, but not limited to, silicon (Si) doped with a Ptype material (e.g., boron) or doped with an Ntype material (e.g., arsenic, phosphorus), or other like doped, silicon material. In some implementations, the second-type (e.g., P-type/N-type doped) semiconductor layers 530 may be composed of a polysilicon material with an opposite doping relative to the doped silicon material, including, but not limited to, polysilicon doped with a Ptype material (e.g., boron) or doped with an Ntype (e.g., Arsenic, Phosphorus), or other like doped, polysilicon material.

In various aspects of the present disclosure, one structural improvement is provided in the form of perforations in the first-type semiconductor layers 520, which trades-off between electron mobility and bulk thermal conductivity. In some implementations, a non-uniform distribution is utilized for arranging the perforations, which maximizes heat blockage (e.g., due to atomic vibration or phonons), while having minimal impact on the electron flow. Conversely, an even placement of the perforations in the first-type semiconductor layers 520 prevents the atomic vibration or phonons phenomena noted-above and, hence, would lead to an efficiency drop of the thermopile design 500.

FIG. 5B is a schematic diagram illustrating a cross-sectional view of the thermopile design 500 of FIG. 5A along a cutline AA′, according to various aspects of the present disclosure. As shown in FIG. 5B, a thermopile structure 540 includes a substrate 502 supporting a buried oxide (BOX) layer 504. In this semiconductor-on-insulator (SOI) implementation, the thermopile structure 540 includes first-type semiconductor layers 520 on the BOX layer 504. Additionally, the thermopile structure 540 includes the oxide layer 510 on the first-type semiconductor layers 520 and second-type semiconductor layers 530 on the oxide layer 510. In various aspects of the present disclosure, the first-type semiconductor layers 520 are perforated, which supports a desired temperature delta between the CJ1 and CJ2 regions and the HJ region shown in FIG. 5A. In this example, an opening in the second-type semiconductor layers 530, the first-type semiconductor layers 520 and the oxide layer 510 exposes a cavity 506 through the BOX layer 504 and in the substrate 502, proximate the HJ region, as shown in FIG. 5A. The thermopile structure 540 further includes contacts (C) between the first-type semiconductor layers 520 and the second-type semiconductor layers 530 at edges of the cavity 506.

FIG. 5C is a schematic diagram illustrating a cross-sectional view of the thermopile design 500 of FIG. 5A along a cutline BB′, according to various aspects of the present disclosure. As shown in FIG. 5C, a thermopile structure 550 is like the thermopile structure 540 of FIG. 5B and is described using similar reference numbers. As shown in FIG. 5C, the thermopile structure 550 further includes contacts (C) between the first-type semiconductor layers 520 and the second-type semiconductor layers 530 at the edge of the thermopile structure 550 and in the CJ2 region, as shown in FIG. 5A.

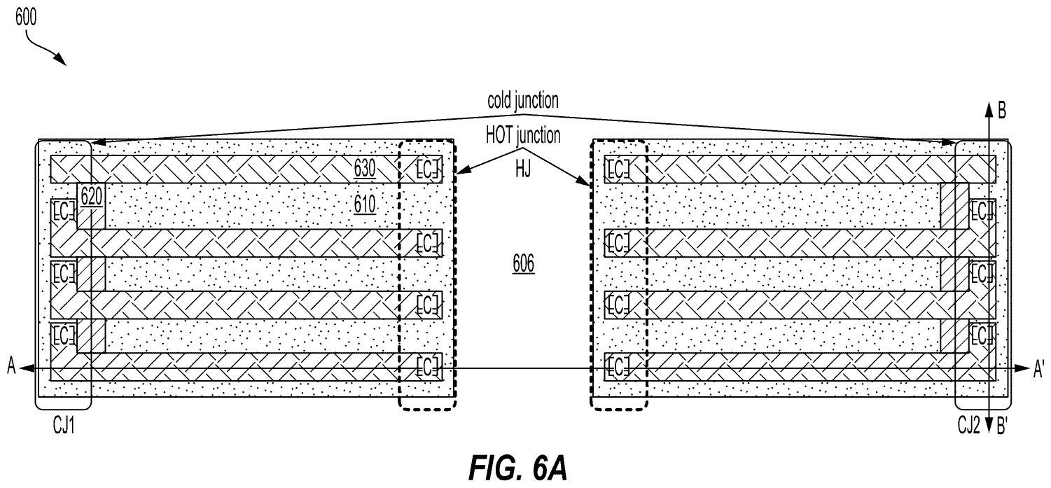

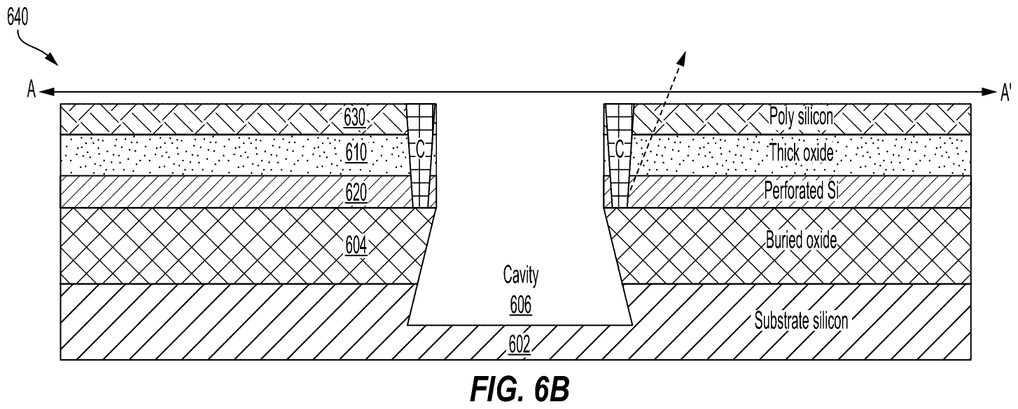

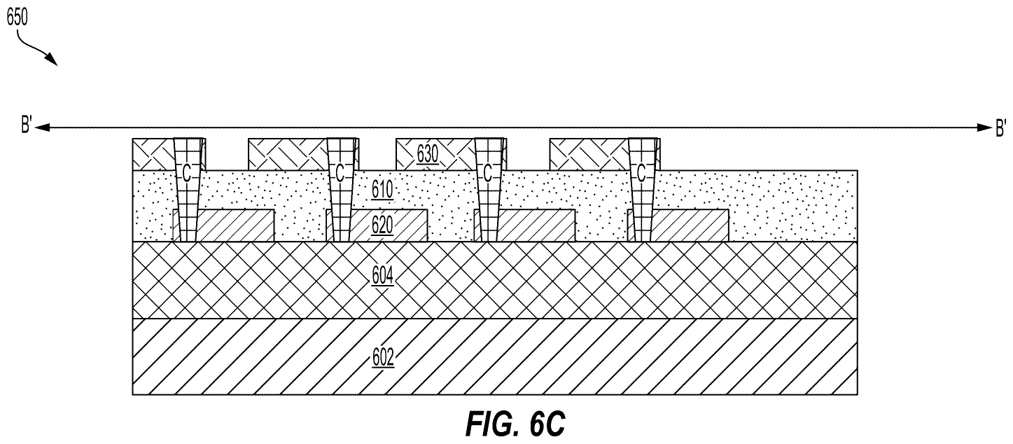

FIGS. 6A-6C are schematic diagrams illustrating a complementary metal oxide semiconductor (CMOS) thermopile design 600 having a perforated semiconductor layer, according to various aspects of the present disclosure. FIG. 6A is a schematic diagram illustrating an overhead layout view of the thermopile design 600, including a cavity 606 proximate a hot junction (HJ) between portions of an oxide layer 610 having a first cold junction (CJ1) and a second cold junction (CJ2). In this example, the thermopile design 600 is composed of first-type semiconductor layers 620 (e.g., diffusion regions) and second-type semiconductor layers 630 (e.g., polysilicon layers) having an opposite doping.

In various aspects of the present disclosure, the first-type semiconductor layers 620 and the second-type semiconductor layers 630 are vertically offset with structural improvements. This arrangement of the first-type semiconductor layers 620 and the second-type semiconductor layers 630 ensures a desired delta (e.g., 0.8-1.5 mV/K) in the Seebeck coefficient by maintaining a temperature delta between the HJ region and the CJ1 and CJ2 regions. In some implementations, the first-type (e.g., N-type/P-type doped) semiconductor layers 620 may be composed of a doped silicon material, including, but not limited to, silicon (Si) doped with a Ptype material (e.g., boron) or doped with an Ntype material (e.g., arsenic, phosphorus), or other like doped, silicon material. In some implementations, the second-type (e.g., P-type/N-type doped) semiconductor layers 630 may be composed of a polysilicon material with an opposite doping relative to the doped silicon material, including, but not limited to, polysilicon doped with a Ptype material (e.g., boron) or doped with an Ntype (e.g., Arsenic, Phosphorus), or other like doped, polysilicon material.

In various aspects of the present disclosure, one structural improvement is provided in the form of perforations in the first-type semiconductor layers 620, which trades-off between electron mobility and bulk thermal conductivity. In some implementations, a non-uniform distribution is utilized for arranging the perforations, which maximizes heat blockage (e.g., due to atomic vibration or phonons), while having minimal impact on the electron flow. Conversely, an even placement of the perforations in the first-type semiconductor layers 620 prevents the atomic vibration or phonons phenomena noted-above and, hence, would lead to an efficiency drop of the thermopile design 600.

FIG. 6B is a schematic diagram illustrating a cross-sectional view of the thermopile design 600 of FIG. 6A along a cutline AA′, according to various aspects of the present disclosure. As shown in FIG. 6B, a thermopile structure 640 includes a substrate 602 supporting a buried oxide (BOX) layer 604. In this semiconductor-on-insulator (SOI) implementation, the thermopile structure 640 includes first-type semiconductor layers 620 on the BOX layer 604. Additionally, the thermopile structure 640 includes the oxide layer 610 on the first-type semiconductor layers 620 and second-type semiconductor layers 630 on the oxide layer 610.

In various aspects of the present disclosure, the first-type semiconductor layers 620 are perforated, which supports a desired temperature delta between the CJ1 and CJ2 regions and the HJ region shown in FIG. 6A. In this example, an opening in the second-type semiconductor layers 630, the first-type semiconductor layers 620, and the oxide layer 610 exposes a cavity 606 through the BOX layer 604 and in the substrate 602, proximate the HJ region, as shown in FIG. 6A. The thermopile structure 640 further includes contacts (C) between sidewalls of the first-type semiconductor layers 620 and the second-type semiconductor layers 630 at edges of the cavity 606. In this example, the contacts C are overflowed to contact the first-type semiconductor layers 620 at the sidewall and on the BOX layer 604.

FIG. 6C is a schematic diagram illustrating a cross-sectional view of the thermopile design 600 of FIG. 6A along a cutline BB′, according to various aspects of the present disclosure. As shown in FIG. 6C, a thermopile structure 650 is like the thermopile structure 640 of FIG. 6B and is described using similar reference numbers. As shown in FIG. 6C, the thermopile structure 650 further includes contacts (C) between the first-type semiconductor layers 620 and the second-type semiconductor layers 630 at the edge of the thermopile structure 650 and in the CJ2 region, as shown in FIG. 6A. In this example, the contacts C are overflowed to abut the first-type semiconductor layers 620 at the sidewall and land on the BOX layer 604.

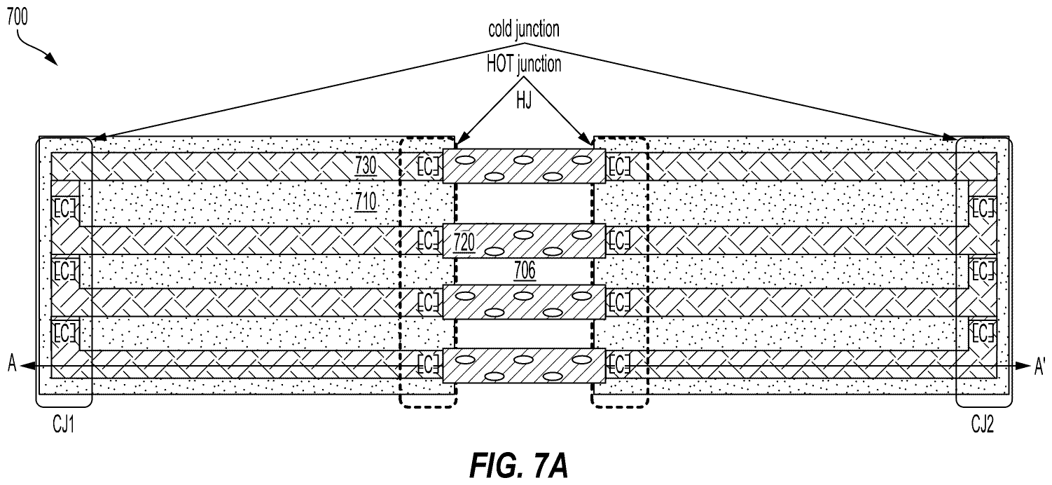

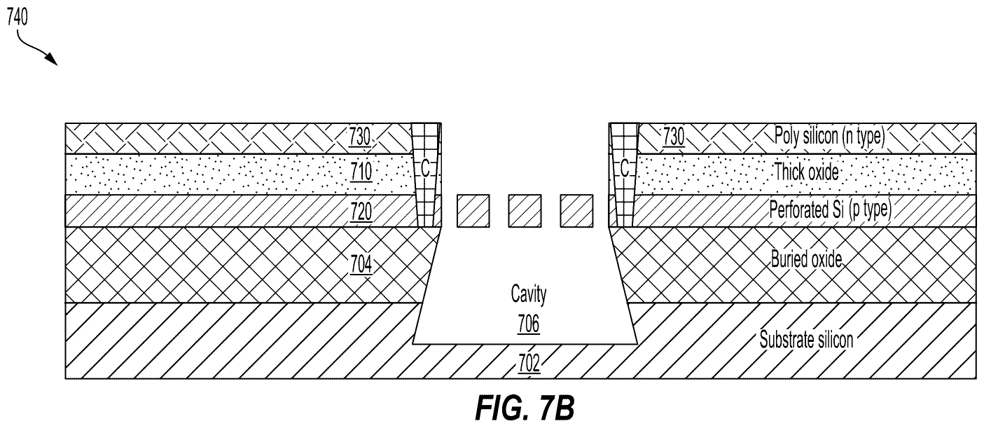

FIGS. 7A and 7B are schematic diagrams illustrating a complementary metal oxide semiconductor (CMOS) thermopile design having a perforated semiconductor layer, according to various aspects of the present disclosure. FIG. 7A is a schematic diagram illustrating an overhead layout view of a CMOS thermopile design 700, including a cavity 706 proximate a hot junction (HJ) between portions of an oxide layer 710 having a first cold junction (CJ1) and a second cold junction (CJ2). In this example, the CMOS thermopile design 700 is composed of first-type semiconductor layers 720 and second-type semiconductor layers 730.

In various aspects of the present disclosure, the first-type semiconductor layers 720 and the second-type semiconductor layers 730 are vertically offset with structural improvements. This arrangement of the first-type semiconductor layers 720 and the second-type semiconductor layers 730 ensures a desired delta (e.g., 0.8-1.5 mV/K) in the Seebeck coefficient along with lower thermal conductivity through the CMOS thermopile design 700 by maintaining a temperature delta between the HJ region and the CJ1 and CJ2 regions according to a generated electromotive force (EMV) in unit of voltage (V) based on Equation (1):

Generated EMF [V]=[seebeck(ntype)−seebeck(ptype)]*(Thot−Tcold)*# of branches (1)

In Equation (1), voltage (V) is unit for the electro-motive force (EMF). The number of branches refers to the number of hot junctions and cold junctions are formed. In operation, each of the branches contributes in parallel to the total voltage generated assuming each branch has the same hot and cold temperature delta.

In some implementations, the first-type (e.g., N-type/P-type) semiconductor layers 720 may be composed of a doped silicon material, including, but not limited to, silicon (Si) doped with a Ptype material (e.g., boron) or doped with an Ntype material (e.g., arsenic, phosphorus), or other like doped, silicon material. In some implementations, the second-type (e.g., P-type/N-type) semiconductor layers 730 may be composed of a doped polysilicon material with an opposite doping relative to the first-type semiconductor layers 720, including, but not limited to, polysilicon doped with a Ptype material (e.g., boron) or doped with an Ntype (e.g., Arsenic, Phosphorus), or other like doped, polysilicon material.

In various aspects of the present disclosure, one structural improvement is provided in the form of perforations in the first-type semiconductor layers 720, which trades-off between electron mobility and bulk thermal conductivity. In some implementations, a non-uniform distribution is utilized for arranging the perforations, which maximizes heat blockage (e.g., due to atomic vibration or phonons), while having minimal impact on the electron flow. Conversely, an even placement of the perforations in the first-type semiconductor layers 720 prevents the atomic vibration or phonons phenomena noted-above and, hence, would lead to an efficiency drop of the thermopile design 700.

FIG. 7B is a schematic diagram illustrating a cross-sectional view of the CMOS thermopile design 700 of FIG. 7A along a cutline AA′, according to various aspects of the present disclosure. As shown in FIG. 7B, a CMOS thermopile structure 740 includes a substrate 702 supporting a buried oxide (BOX) layer 704. In this semiconductor-on-insulator (SOI) implementation, the CMOS thermopile structure 740 includes first-type semiconductor layers 720 on the BOX layer 704. Additionally, the CMOS thermopile structure 740 includes the oxide layer 710 on the first-type semiconductor layers 720 and second-type semiconductor layers 730 on the oxide layer 710. In various aspects of the present disclosure, a perforated portion of the first-type semiconductor layers 720 is exposed through an opening in the second-type semiconductor layers 730 and the oxide layer 710.

According to various aspects of the present disclosure, the CMOS thermopile structure 740 includes a cavity 706 through the BOX layer 704 and in the substrate 702, proximate the HJ region, as shown in FIG. 7A. The CMOS thermopile structure 740 further includes contacts (C) between the first-type semiconductor layers 720 and the second-type semiconductor layers 730 at edges of the cavity 706. FIGS. 4B-4E, 5B-5C, 6B-6C, and FIG. 7B illustrate various implementations of the contacts (C). For example, the contacts in FIGS. 6B-6C are shown as landing on the side of the first-type semiconductor layers 620 (e.g., contacting on the side). In FIGS. 4B-4E and 5B-5C, the contacts (C) on the first-type semiconductor layers 420/520. There are two benefits of the contact formation shown in FIGS. 6B-6C relative to the contact formation shown in FIGS. 4B-4E and 5B-5C. First, the area of contact between the first-type semiconductor layers 620 and the contact is larger in FIGS. 6B-6C (e.g., sidewall contact) relative to the top contact shown in FIGS. 4B-4E and 5B-5C. Second, an etch control to land a contact on the side is easier (etch end detection by an etch stop layer (e.g., BOX layer 604)) in FIGS. 6B-6C (e.g., sidewall contact) compared to the top contact shown in FIGS. 4B-4E and 5B-5C, which involves a precise timed etch that is not well controlled in high volume manufacturing.

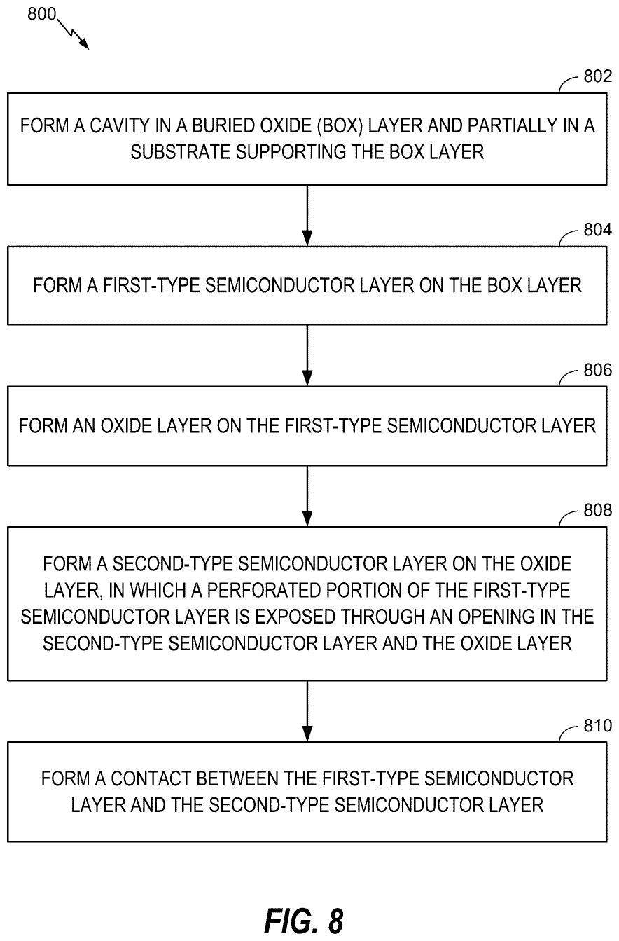

FIG. 8 is a process flow diagram illustrating a method 800 for fabricating a complementary metal oxide semiconductor (CMOS) thermopile structure, according to various aspects of the present disclosure. The method 800 begins at block 802, in which a cavity is formed in a buried oxide (BOX) layer and partially in a substrate supporting the BOX layer. For example, as shown in FIG. 4A is a schematic diagram illustrating an overhead layout view of the thermopile design 400, including a cavity 406 proximate a hot junction (HJ) between portions of an oxide layer 410 having a first cold junction (CJ1) and a second cold junction (CJ2). The thermopile structure 440 includes a cavity 406 through the BOX layer 404 and partially in the substrate 402, proximate the HJ region, as shown in FIG. 4A.

At block 804, a first-type semiconductor layer is formed on the BOX layer. At block 806, an oxide layer is formed on the first-type semiconductor layer. For example, as shown in FIG. 4B, the thermopile structure 440 includes first-type semiconductor layers 420 on portions of the BOX layer 404. Additionally, the thermopile structure 440 includes the oxide layer 410 on the first-type semiconductor layers 420.

At block 808, a second-type semiconductor layer is formed on the oxide layer, in which a perforated portion of the first-type semiconductor layer is exposed through an opening in the second-type semiconductor layer and the oxide layer. For example, as shown in FIG. 4B, the thermopile structure 440 includes the second-type semiconductor layers 430 on the oxide layer 410. In various aspects of the present disclosure, a perforated portion of the first-type semiconductor layers 420 is exposed through an opening in the second-type semiconductor layers 430 and the oxide layer 410.

At block 810, a contact is formed between the first-type semiconductor layer and the second-type semiconductor layer. For example, as shown in FIG. 4B, the thermopile structure 440 further includes a contact (C) between the first-type semiconductor layers 420 and the second-type semiconductor layers 430. As in FIG. 4C, the thermopile structure 450 further includes contacts (C) between the first-type semiconductor layers 420 and the second-type semiconductor layers 430 at the edges of the thermopile structure 450, rather than the edges of the cavity 406, as shown in FIG. 4B.

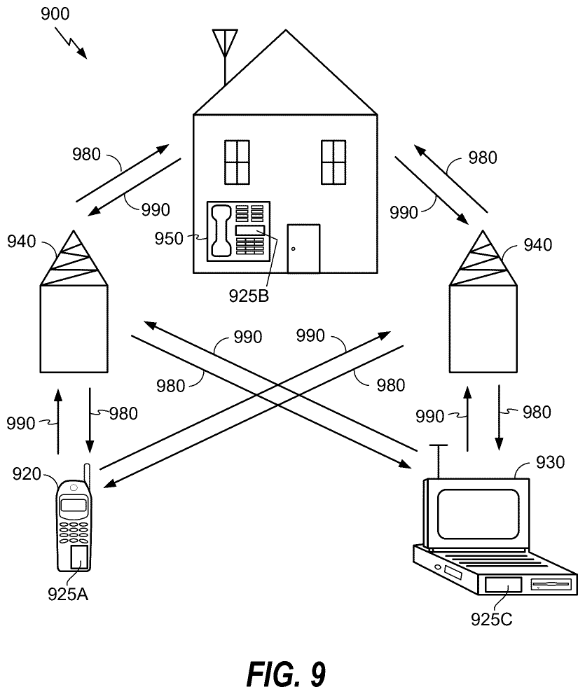

FIG. 9 is a block diagram showing an exemplary wireless communications system 900, in which an aspect of the present disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925B, and 925C that include the disclosed complementary metal oxide semiconductor (CMOS) thermopile structure. It will be recognized that other devices may also include the disclosed CMOS thermopile structure, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the disclosure is not limited to these exemplary illustrated units. Aspects of the present disclosure may be suitably employed in many devices, which include the disclosed CMOS thermopile structure.

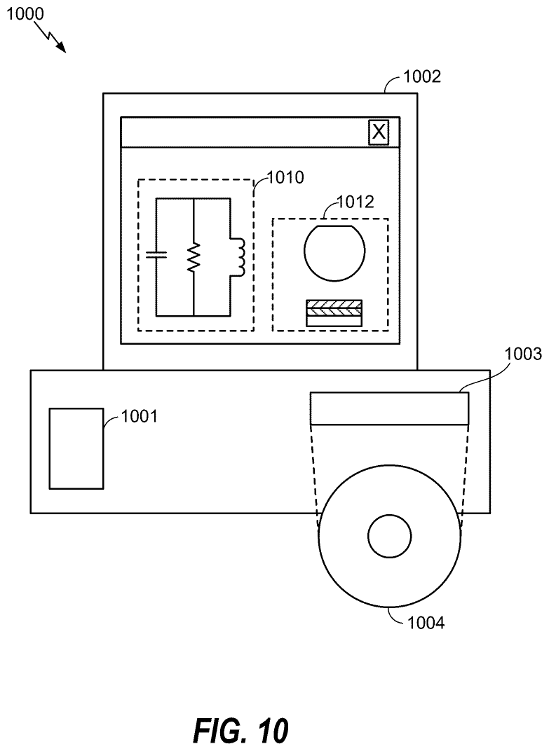

FIG. 10 is a block diagram illustrating a design workstation 1000 used for circuit, layout, and logic design of a semiconductor component, such as the CMOS thermopile structure disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the 3D stacked chip. A storage medium 1004 is provided for tangibly storing the design of the circuit 1010 or the semiconductor component 1012 (e.g., the CMOS thermopile structure). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. An integrated circuit (IC), comprising:
a substrate supporting a buried oxide (BOX) layer;
a first-type semiconductor layer on the BOX layer;
an oxide layer on the first-type semiconductor layer;
a second-type semiconductor layer on the oxide layer, in which a perforated portion of the first-type semiconductor layer is exposed through an opening in the second-type semiconductor layer and the oxide layer;
a contact between the first-type semiconductor layer and the second-type semiconductor layer; and
the BOX layer defining a cavity and partially in the substrate.
2. The IC of clause 1, in which the second-type semiconductor layer comprises a doped polysilicon material.
3. The IC of clause 1, in which the first-type semiconductor layer comprises a doped silicon material.
4. The IC of any of clauses 1-3, in which the first-type semiconductor layer is vertically offset from the second-type semiconductor layer.
5. The IC of any of clauses 1-3, in which the first-type semiconductor layer and the second-type semiconductor layer are staggered and vertically offset.
6. The IC of any of clauses 1-5, in which the contact is proximate a hot junction of the IC.
7. The IC of any of clauses 1-5, in which the contact is proximate a cold junction of the IC.
8. The IC of any of clauses 1-7, in which the cavity is proximate a hot junction of the IC.
9. The IC of any of clauses 1-8, in which the substrate comprises a bulk silicon substrate.
10. The IC of any of clauses 1-9, in which the contact is disposed to abut a sidewall of the first-type semiconductor layer.
11. A method for forming a complementary metal oxide semiconductor (CMOS) thermopile structure, the method comprising:
forming a cavity in a buried oxide (BOX) layer and partially in a substrate supporting the BOX layer;
forming a first-type semiconductor layer on the BOX layer;
forming an oxide layer on the first-type semiconductor layer;
forming a second-type semiconductor layer on the oxide layer, in which a perforated portion of the first-type semiconductor layer is exposed through an opening in the second-type semiconductor layer and the oxide layer; and
forming a contact between the first-type semiconductor layer and the second-type semiconductor layer.
12. The method of clause 11, in which the second-type semiconductor layer comprises a doped polysilicon material.
13. The method of clause 11, in which the first-type semiconductor layer comprises a doped silicon material.
14. The method of any of clauses 11-13, in which the first-type semiconductor layer is vertically offset from the second-type semiconductor layer.
15. The method of any of clauses 11-13, in which the first-type semiconductor layer and the second-type semiconductor layer are staggered and vertically offset.
16. The method of any of clauses 11-15, in which the contact is proximate a hot junction of the IC.
17. The method of any of clauses 11-15, in which the contact is proximate a cold junction of the IC.
18. The method of any of clauses 11-17, in which the cavity is proximate a hot junction of the IC.
19. The method of any of clauses 11-18, in which the substrate comprises a bulk silicon substrate.
20. The method of any of clauses 11-19, in which the contact is disposed to abut a sidewall of the first-type semiconductor layer.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. An integrated circuit (IC), comprising:
a substrate supporting a buried oxide (BOX) layer;
a first-type semiconductor layer on the BOX layer;
an oxide layer on the first-type semiconductor layer;
a second-type semiconductor layer on the oxide layer, in which a perforated portion of the first-type semiconductor layer is exposed through an opening in the second-type semiconductor layer and the oxide layer;
a contact between the first-type semiconductor layer and the second-type semiconductor layer; and
the BOX layer defining a cavity and partially in the substrate.

2. The IC of claim 1, in which the second-type semiconductor layer comprises a doped polysilicon material.

3. The IC of claim 1, in which the first-type semiconductor layer comprises a doped silicon material.

4. The IC of claim 1, in which the first-type semiconductor layer is vertically offset from the second-type semiconductor layer.

5. The IC of claim 1, in which the first-type semiconductor layer and the second-type semiconductor layer are staggered and vertically offset.

6. The IC of claim 1, in which the contact is proximate a hot junction of the IC.

7. The IC of claim 1, in which the contact is proximate a cold junction of the IC.

8. The IC of claim 1, in which the cavity is proximate a hot junction of the IC.

9. The IC of claim 1, in which the substrate comprises a bulk silicon substrate.

10. The IC of claim 1, in which the contact is disposed to abut a sidewall of the first-type semiconductor layer.

11. A method for forming a complementary metal oxide semiconductor (CMOS) thermopile structure, the method comprising:
forming a cavity in a buried oxide (BOX) layer and partially in a substrate supporting the BOX layer;
forming a first-type semiconductor layer on the BOX layer;
forming an oxide layer on the first-type semiconductor layer;
forming a second-type semiconductor layer on the oxide layer, in which a perforated portion of the first-type semiconductor layer is exposed through an opening in the second-type semiconductor layer and the oxide layer; and
forming a contact between the first-type semiconductor layer and the second-type semiconductor layer.

12. The method of claim 11, in which the second-type semiconductor layer comprises a doped polysilicon material.

13. The method of claim 11, in which the first-type semiconductor layer comprises a doped silicon material.

14. The method of claim 11, in which the first-type semiconductor layer is vertically offset from the second-type semiconductor layer.

15. The method of claim 11, in which the first-type semiconductor layer and the second-type semiconductor layer are staggered and vertically offset.

16. The method of claim 11, in which the contact is proximate a hot junction of the IC.

17. The method of claim 11, in which the contact is proximate a cold junction of the IC.

18. The method of claim 11, in which the cavity is proximate a hot junction of the IC.

19. The method of claim 11, in which the substrate comprises a bulk silicon substrate.

20. The method of claim 11, in which the contact is disposed to abut a sidewall of the first-type semiconductor layer.
